(19) United States
(12) Patent Application Publication
(10) Pub. No.: US 2015/0041930 A1
(43) Pub. Date: Feb. 12, 2015

(54) ACOUSTIC TRANSDUCER

(71) Applicant: SAMSUNG ELECTRO-MECHANICS CO., LTD., Suwon (KR)

(72) Inventors: Jong Beom Kim, Suwon (KR); Yoon Sok Park, Suwon (KR); Jung Won Lee, Suwon (KR); Hyun Ho Lim, Suwon (KR); Byeong Sung Min, Suwon (KR)

(73) Assignee: SAMSUNG ELECTRO-MECHANICS CO., LTD., Suwon (KR)

(21) Appl. No.: 14/080,239

(22) Filed: Nov. 14, 2013

(30) Foreign Application Priority Data
Aug. 9, 2013 (KR) 10-2013-0094548
Sep. 5, 2013 (KR) 10-2013-0106656

(51) Int. Cl. H04R 19/00; H04R 1/00; B81B 3/00; H04R 19/04

(52) U.S. Cl. CPC H04R 19/005; H04R 19/04; H04R 1/00; B81B 3/0021; H04R 2201/003; B81B 2201/0257
USPC 257/416

(57) ABSTRACT

There is provided an acoustic transducer including: a substrate formed to have a hollow part through which acoustic waves are input; a diaphragm formed on the substrate and covering the hollow part; and a back plate disposed so as to cover at least a portion of the diaphragm, wherein a ring-shaped groove extended along an edge of the diaphragm is formed in the substrate.

### CROSS-REFERENCE TO RELATED APPLICATIONS

This application claims the benefit of Korean Patent Application Nos. 10-2013-0094548, filed on Aug. 9, 2013, and 10-2013-0106656, filed on Sep. 5, 2013, with the Korean Intellectual Property Office, the disclosures of which are incorporated herein by reference.

### BACKGROUND

1. Field of the Invention

The present invention relates to an acoustic transducer and a method of manufacturing the same, and more particularly, to an acoustic transducer manufactured using microelectromechanical system (MEMS) technology.

2. Description of the Related Art

In accordance with the recent trend for the miniaturization of electronic products, components mounted therein have gradually been miniaturized. Therefore, a microelectromechanical system (MEMS) acoustic transducer has been preferable as an acoustic signal input device widely used in mobile communication terminals, audio apparatuses, and the like.

Such a MEMS acoustic transducer may be classified as a piezoresistive-type MEMS acoustic transducer, a piezoelectric-type MEMS acoustic transducer, or a condenser-type MEMS acoustic transducer.

Since such a piezoresistive type MEMS acoustic transducer uses the principle that a resistance value is changed by vibrations, the resistance value may be changed according to changes in the surrounding environment (changes in temperature, levels of humidity and dust, and the like), such that a constant register frequency may not be maintained.

In addition, since the piezoelectric type MEMS acoustic transducer uses a piezoelectric effect in which a potential difference is generated between both ends of a vibration plate, an electric signal may be changed according to pressure of an sound signal, while low band and voice band frequency characteristics are non-uniform, such that there are significant limitations on commercializing such piezoelectric-type MEMS acoustic transducers.

On the other hand, the condenser-type MEMS acoustic transducer has a structure in which one of two metal plates serves as a fixed electrode, while the other metal plate serves as a vibration plate reflecting an acoustic signal to cause vibrations, and an air gap having a size of several to several tens of μm is formed between two electrodes. In such a condenser-type MEMS acoustic transducer, when the vibration plate vibrates according to a sound source, changes in capacitance between the vibration plate and the fixed electrode are measured, such that there are advantages such as stability of conversion register and excellent frequency characteristics.

Therefore, the condenser-type MEMS acoustic transducer has been mainly used.

Referring to FIG. 1, a general condenser-type MEMS acoustic transducer according to the related art includes a substrate 1, a diaphragm 2, a spacer 3, and a back plate.

Meanwhile, performance of the condenser-type MEMS acoustic transducer is directly associated with sensitivity of the diaphragm used as a vibration plate. The thinner the plate and the wider the area thereof, the more excellent the sensitivity of diaphragm. However, there is a limitation in decreasing the thickness of the diaphragm and increasing the area due to technical limitations and cost.

Further, since the diaphragm 2 has a shape in which a predetermined section of a distal end thereof is fixed to the substrate 1, sensitivity in of the diaphragm in terms of vertical vibrations, according to the input acoustic pressure, is inevitably limited.

### RELATED ART DOCUMENT

(Patent Document 1) U.S. Pat. No. 6,535,460 B2
(Patent Document 2) U.S. Pat. No. 7,449,356
(Patent Document 3) U.S. Pat. No. 7,912,236 B2

### SUMMARY

An aspect of the present invention provides an acoustic transducer capable of increasing a degree of freedom in vertical vibrations of a diaphragm to improve sensitivity in sensing acoustic waves.

According to an aspect of the present invention, there is provided an acoustic transducer including: a substrate formed to have a hollow part through which acoustic waves are input; a diaphragm formed on the substrate and covering the hollow part; and a back plate disposed so as to cover at least a portion of the diaphragm, wherein a ring-shaped groove extended along an edge of the diaphragm is formed in the substrate.

The back plate may include a support part extended toward the edge of the diaphragm.

A longitudinal cross section of the support part may have a trapezoidal, triangular, or semi-circular shape.

The diaphragm may be formed of a conductive material and the back plate may include an electrode formed thereon, such that an electric field may be formed between the diaphragm and the back plate.

A support structure may be formed between the diaphragm and the back plate.

The support part may be disposed to have a circular shape at a predetermined interval based on the diaphragm.

The support part may be ring-shaped, having a predetermined diameter based on the diaphragm.

The groove may have a cross-sectional shape in which a depth of the groove increases as a distance from the diaphragm increases.

According to another aspect of the present invention, there is provided an acoustic transducer including: a substrate formed to have a hollow part through which acoustic waves are input; a diaphragm formed on the substrate, covering the hollow part, and formed of a conductive material; a back plate including a fixed upper electrode formed thereon; and a support structure formed between the diaphragm and the back plate and including a support part extended toward an edge of the diaphragm, wherein a ring-shaped groove extended along the edge of the diaphragm is formed in the substrate.

The support part may be disposed to have a circular shape at a predetermined interval based on the diaphragm.

The support part may be ring-shaped, having a predetermined diameter based on the diaphragm.

The groove may have a cross-sectional shape in which a depth of the groove increases as a distance from the diaphragm increases.

A longitudinal cross section of the support part may have a trapezoidal, triangular, or semi-circular shape.

According to another aspect of the present invention, there is provided an acoustic transducer including: a substrate including a hollow part; a second support structure including a second support part protruding upwardly along an outer side of the hollow part and attached onto an upper surface of the substrate; a first support structure including a first support part protruding downwardly at a position corresponding to the second support part; a thin film type diaphragm positioned between the first and second support parts and having an outer line formed at the outside of an inner surface of an upper end of the hollow part in a radial direction so as to completely cover the hollow part; and a fixed upper electrode provided over the diaphragm to form a capacitor through interaction with the diaphragm in a position facing the diaphragm.

The diaphragm may be positioned to be spaced apart from the first and second support parts.

The acoustic transducer may further include a back plate including a plurality of sound holes and fixed to the first support structure, wherein the fixed upper electrode is attached to a lower surface of the back plate.

The second support structure may be spaced apart from the upper surface of the substrate at a predetermined section in the radial direction to thereby have elasticity in a vertical direction, and the first support structure may be spaced apart from a lower surface of the fixed upper electrode at a predetermined section in the radial direction to thereby have elasticity in the vertical direction.

The acoustic transducer may further include an auxiliary plate attached to the upper surface of the substrate, positioned below the diaphragm, covering the hollow part, and including a plurality of holes.

The auxiliary plate may be a lower fixed electrode formed of a conductive material so as to form a capacitor through interaction with the diaphragm.

The first and second support parts may have a continuous closed curve shape.

The first and second support parts may be a plurality of bumps, and the first and second support structures may have a saw-tooth shape having groove parts between the first and second supports parts, respectively.

The diaphragm may have a disk shape.

According to another aspect of the present invention, there is provided an acoustic transducer including: a substrate including a hollow part; a second support structure including a second support part protruding upwardly along an outer side of the hollow part and attached onto an upper surface of the substrate; a first support structure including a first support part protruding downwardly at a position corresponding to the second support part; a thin film type diaphragm positioned between the first and second support parts and having an outer line formed at the outside of an inner surface of an upper end of the hollow part in a radial direction so as to completely cover the hollow part; and a lower fixed electrode attached onto the upper surface of the substrate, positioned below the diaphragm, including a plurality of holes, and formed of a conductive material so as to form a capacitor through interaction with the diaphragm.

The diaphragm may be positioned to be spaced apart from the first and second support parts.

The first support structure may be spaced apart from the upper surface of the substrate at a predetermined section in the radial direction to thereby have elasticity in a vertical direction.

The first and second support parts may have a continuous closed curve shape.

The first and second support parts may be a plurality of bumps, and the first and second support structures may have a saw-tooth shape having groove parts between the first and second supports parts, respectively.

The diaphragm may have a disk shape.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view of an acoustic transducer according to the related art;

FIG. 2 is a cross-sectional view of an acoustic transducer according to a first embodiment of the present invention;

FIG. 3 is a plan view of the acoustic transducer shown in FIG. 2;

FIG. 4 is a plan view of another form of the acoustic transducer shown in FIG. 2;

FIG. 5 is a plan view of another form of the acoustic transducer shown in FIG. 2;

FIGS. 6A through 6D are enlarged views showing examples of part A shown in FIG. 2;

FIG. 7 is a cross-sectional view of an acoustic transducer according to a second embodiment of the present invention;

FIG. 8 is a plan view of the acoustic transducer shown in FIG. 7;

FIG. 9 is a cross-sectional view of another form of the acoustic transducer shown in FIG. 7;

FIGS. 10A through 10D are enlarged views showing examples of part B shown in FIG. 7;

FIGS. 11A and 11B are partially cut-away perspective views of acoustic transducers according to a third embodiment of the present invention;

FIG. 12 is a cross-sectional view of the acoustic transducer shown in FIGS. 11A and 11B;

FIGS. 13A and 13B are plan views of the acoustic transducers shown in FIGS. 11A and 11B, respectively;

FIGS. 14A and 14B are partially cut-away perspective views of acoustic transducers according to a fourth embodiment of the present invention;

FIG. 15 is a cross-sectional view of the acoustic transducer shown in FIGS. 14A and 14B; and

FIGS. 16A and 16B are plan views of the acoustic transducers shown in FIGS. 14A and 14B, respectively.

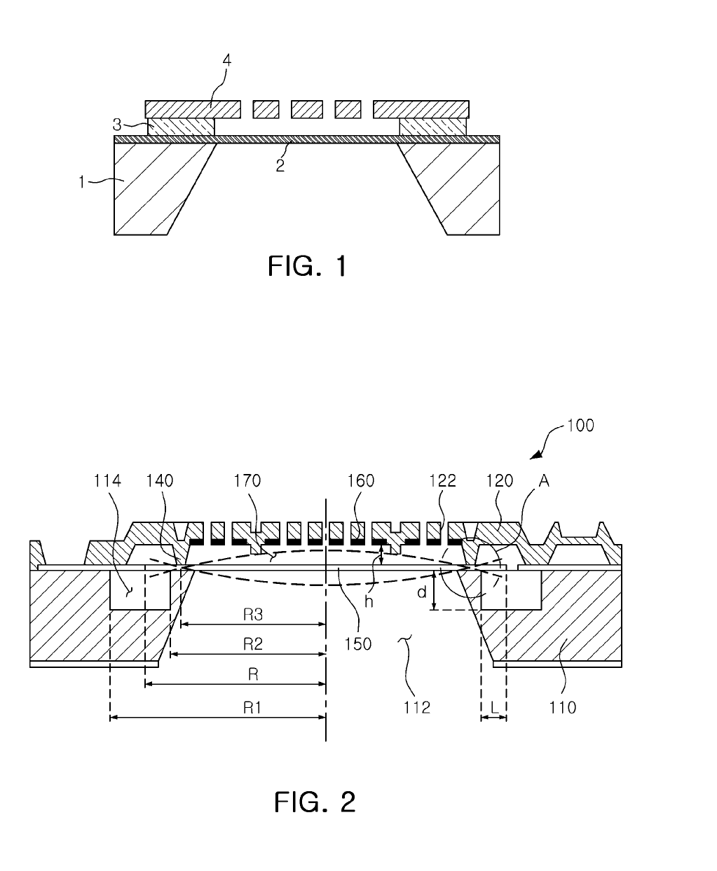

### DETAILED DESCRIPTION

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

### First Embodiment

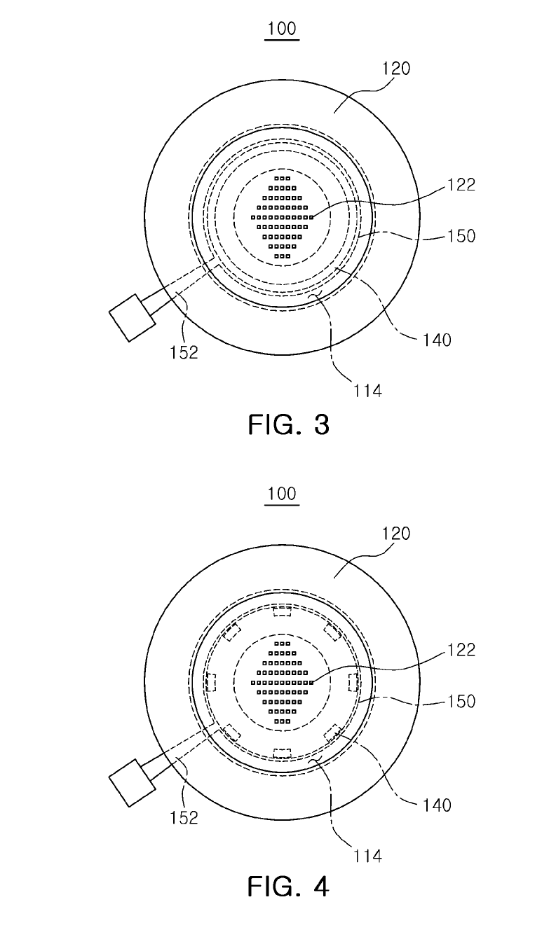

FIG. 2 is a cross-sectional view of an acoustic transducer according to a first embodiment of the present invention, FIG. 3 is a plan view of the acoustic transducer shown in FIG. 2, and FIG. 4 is a plan view of another form of the acoustic transducer shown in FIG. 2.

Referring to FIGS. 2 through 6D, the acoustic transducer 100 according to the first embodiment of the present invention may include a substrate 110, a back plate 120, a diaphragm 150, and a fixed upper electrode 160. The acoustic transducer 100 configured as described above may be mounted in a portable terminal, a small sized electronic device, or the like. In addition, the acoustic transducer 100 maybe mounted in a device requiring a function of sensing acoustic sound, converting the acoustic sound into an electric signal, or the like.

Hereinafter, components of the acoustic transducer 100 will be described.

The substrate 110 may be formed of single crystalline silicon or a silicon on insulator (SOI) material. In addition, the substrate 110 may have a shape in which at least one silicon layer is laminated.

The substrate 110 may form a body of the acoustic transducer 100. Alternatively, the substrate 110 may be a portion of a portable terminal or a small-sized electronic device in which the acoustic transducer 100 is mounted. For example, the substrate 110 may be a portion of a semiconductor package mounted in the portable terminal.

A hollow part 112 may be formed in the substrate 110. The hollow part 112 may be formed by mechanical or chemical processing. For example, the hollow part 112 may be formed by a wet or dry etching process. The hollow part 112 formed as described above may be used as a space through which acoustic waves are input.

A cross-section of the hollow part 112 may have a shape in which it is gradually decreased from one surface (a lower surface based on FIG. 2) of the substrate 110 toward the other surface thereof (an upper surface based on FIG. 2). This cross-sectional shape may be effective for concentrating acoustic waves input from the outside on one point. However, the cross-sectional shape of the hollow part 112 is not limited to the above-mentioned shape.

A groove 114 may be formed in the substrate 110. In detail, the groove 114 may be formed to have a ring shape based on the hollow part 112. Here, an outer radius R1 of the groove 114 may be larger than a radius R of the diaphragm 150, and an inner radius R2 of the groove 114 may be smaller than the radius R of the diaphragm 150.

The groove 114 may have a predetermined depth d. Here, the depth d may be equal to or larger than a length L of a portion of the diaphragm 150 protruding outwardly from the groove 114. The groove 114 as described above may be formed by mechanical or chemical processing, similarly to the hollow part 112. For example, the hollow part 114 may be formed by an etching process using a photo resist.

The diaphragm 150 may be disposed on one surface (the upper surface based on FIG. 2) of the substrate 110 and disposed so as to completely cover the hollow part 112. The diaphragm 150 disposed as described above may vibrate in a vertical direction (based on FIG. 2) according to the magnitude of the acoustic waves input through the hollow part 112 or through the backplate 120.

A cross-section of the diaphragm 150 may have a circular shape. For example, the cross-sectional shape of the diaphragm 150 may be a circle having a size different from that of the hollow part 112 and the same center as that of the hollow part 112. However, the cross-sectional shape of the diaphragm 150 is not limited to the circle but may be changed into a polygon having four or more sides.

The diaphragm 150 may be formed of a conductive material. For example, the diaphragm 150 may be formed of a polysilicon thin film having high conductivity. However, the diaphragm 150 is not necessarily formed of the conductive material. For example, the diaphragm 150 may be manufactured in a manner in which one surface is coated with a conductive material or has a conductive film attached thereto.

The diaphragm 150 may include a fixed end part 152 as shown in FIG. 3. The fixed end part 152 may be extended toward one portion of the substrate 110 and connect the diaphragm 150 and external power supply to each other. The diaphragm 150 connected to the external power supply through the fixed end part 152 may form an electrode having a first polarity.

The back plate 120 may be formed on one surface (the upper surface based on FIG. 2) of the substrate 110. In detail, the back plate 120 may be formed so as to completely cover the diaphragm 150.

The back plate 120 may be disposed so as to form a predetermined space 170 with regard to the diaphragm 150. That is, the back plate 120 may cover one surface of the diaphragm 150, having a predetermined distance from the diaphragm 150. Here, a height h of the space 170 may be greater than the amplitude of the diaphragm 150.

The back plate 120 may be formed of an insulating material. For example, the back plate 120 may be formed of silicon nitride (SiN).

The fixed upper electrode 160 may be formed on one surface (a surface facing the diaphragm 150 based on FIG. 2) of the back plate 120. In detail, one surface of the back plate 120 may be formed with the fixed upper electrode 160 having a polarity different from that of the diaphragm 150. Therefore, a predetermined capacitance may be formed between the back plate 120 and the diaphragm 150.

A plurality of through holes 122 may be formed in the back plate 120. Here, the through holes 122 may be used as a path through which the acoustic waves input through the hollow part 112 are discharged. That is, the acoustic waves input through the hollow part 112 may vibrate the diaphragm 150 and then discharged upwardly from the back plate 120 through the through hole 122.

A support part 140 pressing a portion of the diaphragm 150 may be formed on the back plate 120. In detail, the support part 140 may be extended toward the diaphragm 150 to limit a vibration region of the diaphragm 150 vibrated by the acoustic waves. Here, a distance from the center of the diaphragm 150 to the support part 140, (that is, a radius R3) may be smaller than the radius R of the diaphragm 150.

The support part 140 may have a ring shape or closed curve shape in which the support part 140 is extended to be elongated, based on a diaphragm 150, as shown in FIG. 3. However, the shape of the support part 140 is not limited to the ring, but may be a pillar discontinuously formed as shown in FIG. 4, when needed.

The acoustic transducer 100 formed as described above may secure the amplitude of the diaphragm 150 by the groove 114 of the substrate 110 and the support part 140 of the back plate 120. That is, in the present acoustic transducer 100, an edge of the diaphragm 150 maybe bent toward the outsides of the groove 114 and the support 140 as shown by the dotted lines of FIG. 2, a phenomenon that the amplitude of the diaphragm 150 is decreased by a contact between the diaphragm 150 and the substrate 110 or the back plate 120 is not generated.

Therefore, according to the present acoustic transducer 100, the sensitivity of sensing the acoustic waves by vibration of the diaphragm 150 may be improved.

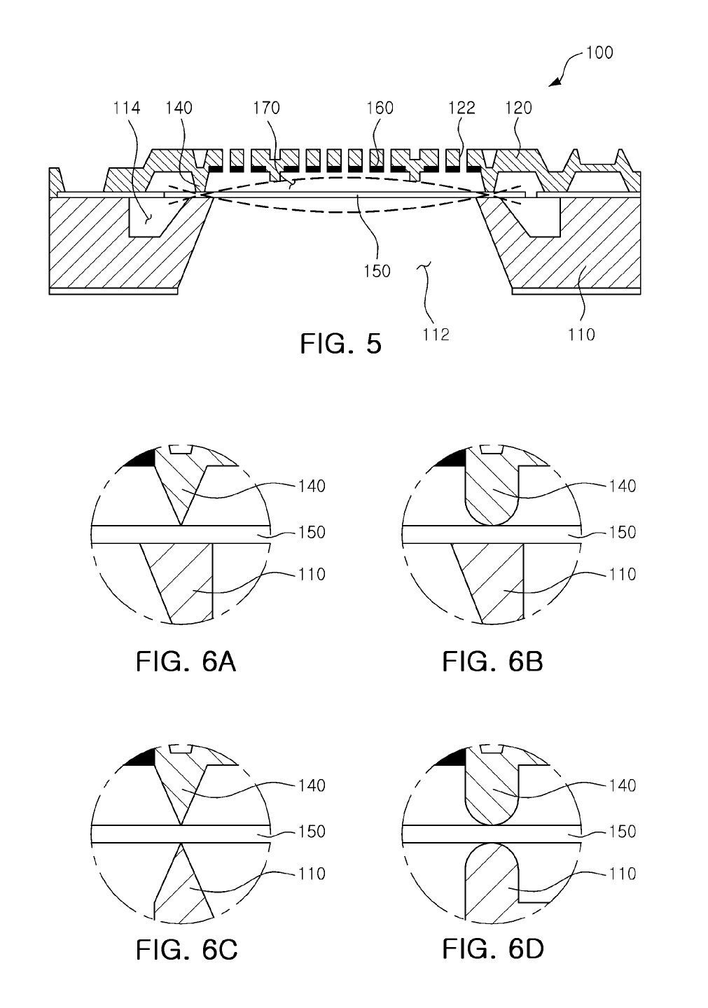

Meanwhile, the acoustic transducer 100 according to the first embodiment may be formed as shown in FIG. 5. In detail, in the acoustic transducer 100, the groove 114 may have a cross-sectional shape in which as a distance from the diaphragm 150 increases, a depth thereof increases.

Further, the acoustic transducer 100 according to the first embodiment may have the support part 140 in various shapes. For example, a longitudinal cross section of the support part 140 may have a (reverse) triangular or semicircular shape as shown in FIGS. 6A and 6B. In addition, a longitudinal cross section of a portion of the substrate 110 contacting the diaphragm 150 may have a triangular or semi-circular shape as shown in FIGS. 6C and 6D. That is, the support part 140 and the substrate 110 may be deformed in a shape in which a contact area with the diaphragm 150 may be significantly decreased.

Since these shapes of the support part 140 and the substrate 110 may facilitate bending deformation of the diaphragm 150, sensitivity of sensing an acoustic wave of the acoustic transducer 100 may be improved.

### Second Embodiment

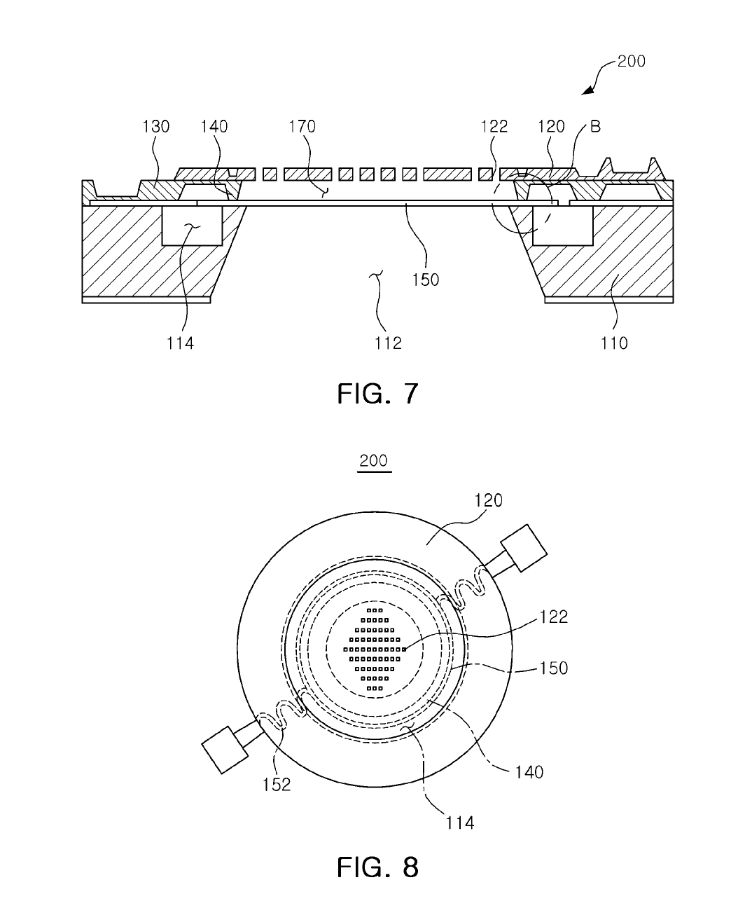

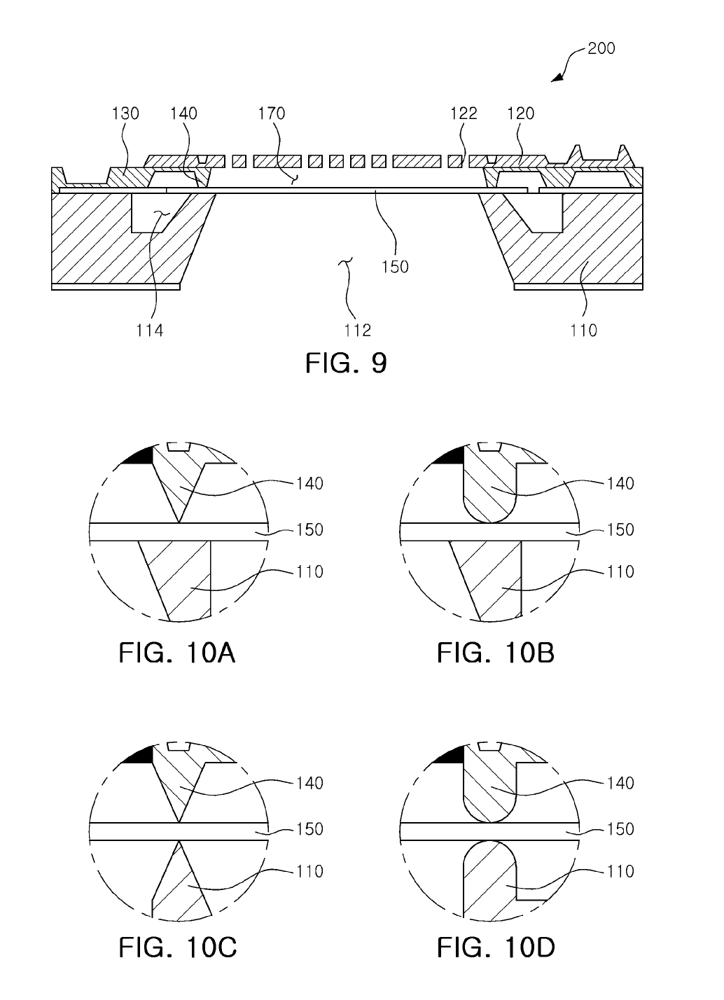

FIG. 7 is a cross-sectional view of an acoustic transducer according to a second embodiment of the present invention, and FIG. 8 is a plan view of the acoustic transducer shown in FIG. 7. FIG. 9 is a cross-sectional view of another form of the acoustic transducer shown in FIG. 7, and FIGS. 10A through 10D are enlarged views showing examples of part B shown in FIG. 7.

Hereinafter, the acoustic transducer according to the second embodiment of the present invention will be described with reference to FIGS. 7 through 10D. For reference, the components described in the above-mentioned embodiment will be denoted by the same reference numerals and a description thereof will be omitted.

The acoustic transducer 200 according to the second embodiment of the present invention may be distinguished from the above-mentioned embodiment in structures of a back plate 120 and a fixed end part 152. Further, the acoustic transducer 200 according to the second embodiment of the present invention may further include an insulating member 130 separately from the back plate 120.

Hereinafter, the configurations distinguished from those in the above-mentioned embodiment will be described in detail.

The insulating member 130 may be formed on one surface of a substrate 110. Further, the insulating member 130 may include at least one support part 140 contacting a diaphragm 150.

The back plate 120 may be formed on one surface of the insulating member 130. Here, the back plate 120 may be formed of a conductive material to form an electrode having a polarity different from that of the diaphragm 150.

The fixed end part 152 may have a zigzag shape as shown in FIG. 8 and the number of fixed end part may be one or more. The fixed end part 152 formed as describe above may sufficiently secure the amplitude of the diaphragm 150 while effectively blocking a position of the diaphragm 150 from being changed by external impact.

Meanwhile, the acoustic transducer 200 according to the second embodiment may be formed as shown in FIG. 9. In detail, in the acoustic transducer 200, a groove 114 may have a cross-sectional shape in which as a distance from the diaphragm 150 increases, a depth thereof increases.

Further, the acoustic transducer 200 according to the second embodiment may have a support part 140 in various shapes. For example, a longitudinal cross section of the support part 140 may have a (reverse) triangular or semicircular shape as shown in FIGS. 10A and 10B. In addition, a longitudinal cross section of a portion of the substrate 110 contacting the diaphragm 150 may have a triangular or semi circular shape as shown in FIGS. 10C and 10D. That is, the support part 140 and the substrate 110 may be deformed in a shape in which a contact area with the diaphragm 150 may be significantly decreased.

Since these shapes of the support part 140 and the substrate 110 may facilitate bending deformation of the diaphragm 150, sensitivity of sensing an acoustic wave of the acoustic transducer 200 may be improved.

### Third Embodiment

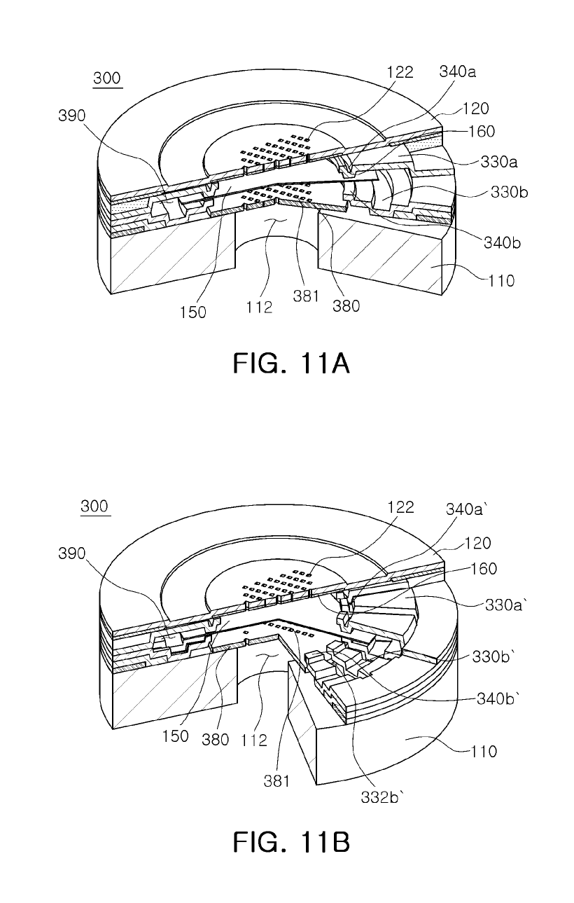

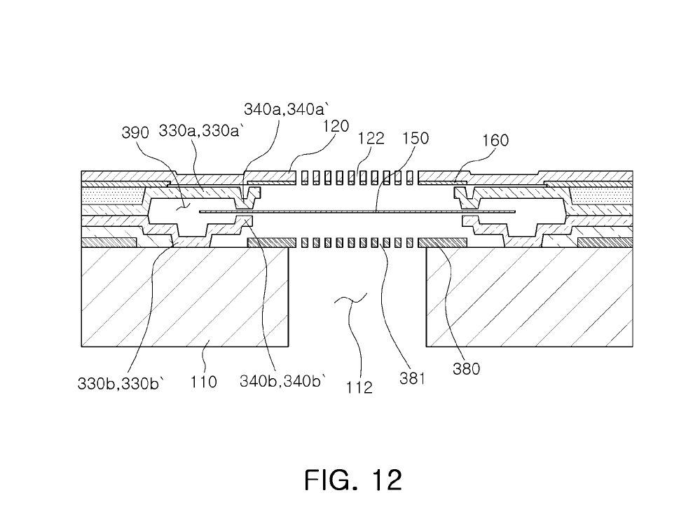

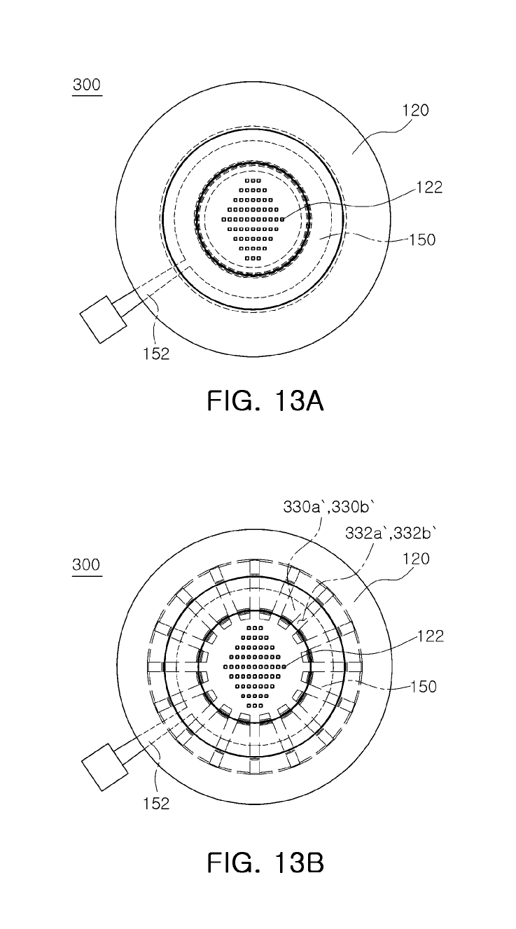

FIGS. 11A and 11B are partially cut-away perspective views of an acoustic transducer according to a third embodiment of the present invention, FIG. 12 is a cross-sectional view of the acoustic transducer shown in FIGS. 11A and 11B, and FIGS. 13A and 13B are plan views of the acoustic transducers shown in FIGS. 11A and 11B, respectively.

Referring to FIGS. 11A through 13B, the acoustic transducer 300 according to the third embodiment of the present invention may include a substrate 110 including a hollow part 112, a second support structure 330b or 330b′ attached onto an upper surface of the substrate, a first support structure 330a or 330a′ positioned over the second support structure 330b or 330b′, a thin film type diaphragm 150 positioned between the first and second support structures 330a or 330a′ and 330b or 330b′, a back plate 120 fixed to the first support structure 330a or 330a′, a fixed upper electrode 160, and an auxiliary plate 380 positioned below the diaphragm 150 to cover the hollow part.

The second support structure 330b or 330b′ may include a second support part 340b or 340b′ attached onto the upper surface of the substrate and protruding upwardly along an outer side of the hollow part 112.

In addition, the first support structure 330a or 330a′ may include a first support part 340a or 340a′ protruding downwardly at a position corresponding to the second support part.

Therefore, as shown in FIG. 12, a space part 390 may be formed at an outer side from the first and second support parts 340a or 340a′ and 340b or 340b′ in a radial direction.

The space part 390 is secured, such that a degree of freedom at a distal end portion of the diaphragm 150 may be secured, thereby improving sensitivity of the diaphragm 150. In other words, when the diaphragm 150 is vibrated by acoustic pressure, since the first and second support structures 330a or 330b and 330a′ or 330b′ do not interfere with the distal end portion of the diaphragm 150, the sensitivity of the diaphragm 150 may be improved.

Meanwhile, a predetermined section of the second support structure 330b or 330b′ in the radial direction may be spaced apart from the upper surface of the substrate, such that the second support structure 330b or 330b′ may have elasticity in a vertical direction.

Similarly, a predetermined section of the first support structure 330a or 330a′ in the radial direction may be spaced apart from a lower surface of the fixed upper electrode 160, such that the first support structure 330a or 330a′ may have elasticity in the vertical direction.

As described above, the first and second support structures 330a or 330a′ and 330b or 330b′ have elasticity in the vertical direction, the sensitivity of the diaphragm 150 may be further improved.

In addition, the first and second support parts 340a or 340a′ and 340b or 340b′ may have a continuous closed curve shape as shown in FIGS. 11A and 13A. Although the first and second support parts 340a or 340a′ and 340b or 340b′ having a ring shape are shown in FIGS. 11A and 13A, the shape thereof is not limited to thereto, but the first and second support parts 340a or 340a′ and 340b or 340b′ may have various shapes as long as a closed curve is formed along the outer side of the hollow part 112.

In addition, the first and second support parts 340a or 340a′ and 340b or 340b′ may be composed of a plurality of discontinuous bumps as shown in FIGS. 11B and 13B. In this case, the plurality of discontinuous bumps may mean a plurality of independent protrusion parts formed along the outer side of the hollow part 112. Meanwhile, referring to FIGS. 11B and 13B, the first and second support structures 330a′ and 330b′ including the first and second support parts 340a′ and 340b′ composed of the plurality of bumps may have a saw-tooth shape, having groove parts 332a′ and 332b′ between the first and second support parts 340a′ and 340b′, respectively.

In the case in which the first and second support structures 330a′ and 330b′ are provided in the saw-tooth shape, since the elasticity in the vertical direction may be increased, the sensitivity of the diaphragm 150 may be further improved.

Meanwhile, the first and second support structures 330a or 330a′ and 330b or 330b′ may be formed of a nonconductive material, for example, silicon nitride (SiN).

The diaphragm 150 may include an outer line formed at the outside of an inner surface of an upper end of the hollow part 112 in the radial direction so as to completely cover the hollow part 112 and be provided as a thin film in a disk shape. The diaphragm 150 may be formed of a conductive material to form a capacitor through interaction with the fixed upper electrode 160. Here, the diaphragm 150 may be formed by applying poly-silicon (poly-Si) using a low pressure chemical vapor deposition (LPCVD) method.

When the acoustic pressure is input, the diaphragm 150 vibrates, and a distance with the fixed upper electrode 160 may be continuously changed by the vibration, such that capacitance of the capacitor formed by the diaphragm 150 and the fixed upper electrode 160 may also be changed, thereby signaling sound by measuring the changed capacitance.

Meanwhile, the diaphragm 150 may be positioned between the first and second support parts 340a or 340a′ and 340b or 340b′ so as to be spaced apart therefrom by a micro gap. The diaphragm 150 is mechanically separated from the first and second support parts 340a or 340a′ and 340b or 340b′ as described above, stress inherent in the diaphragm 150 during a manufacturing process may be removed, which may be directly associated with reliability of the acoustic transducer.

Meanwhile, since the diaphragm 150 is positioned to be spaced apart from the first and second support parts 340a or 340a′ and 340b or 340b′, a means for fixing the diaphragm 150 is required. In this case, the means for fixing the diaphragm 150 may be the fixed end part 152 connecting a circuit part (not shown) for measuring a change in the capacitance and the diaphragm 150 to each other. That is, the diaphragm 150 may be suspended by the fixed end part 152. Meanwhile, the means for fixing the diaphragm 150 is not limited to the fixed end part 152, but a separate suspension means such as a spring (not shown), or the like, may be provided.

The back plate 120 may include a plurality of through holes 122. The acoustic waves may pass through the plurality of through holes 122, and the diaphragm 150 may be vibrated by the acoustic pressure. In addition, the plurality of through holes 122 may simultaneously serve as a dust filter allowing impurities such as dust, or the like, not to be introduced in an air gap formed between the diaphragm 150 and the fixed upper electrode 160.

The fixed upper electrode 160 may be disposed at a position facing the diaphragm 150 and attached to a lower surface of the back plate 120. In addition, as described above, the fixed upper electrode may form the capacitor through interaction with the diaphragm 150.

In addition, the fixed upper electrode 160 may be formed by a process of applying poly-silicon (poly-Si) using the LPCVD.

The auxiliary plate 380 may be attached to the upper surface of the substrate 110 and positioned below the diaphragm 150 to thereby cover the hollow part 112. The auxiliary plate 380 may include a plurality of holes 381. The plurality of holes 381 may allow the diaphragm 150 to be vibrated by the acoustic pressure by passing the acoustic waves, similarly to the plurality of through holes 122, and block impurities such as dust, or the like, from being introduced, thereby improving reliability of the acoustic transducer.

Further, the auxiliary plate 380 may be provided as a lower fixed electrode 380 formed of a conductive material so as to form a capacitor through interaction with the diaphragm 150. Hereinafter, for convenience of description, the auxiliary plate and the lower fixed electrode may be represented by the same reference numeral (380).

As described above, the lower and fixed upper electrodes 380 and 160 are simultaneously provided to form each of the capacitors through interaction with the diaphragm 150, such that the reliability of the acoustic transducer may be improved.

### Fourth Embodiment

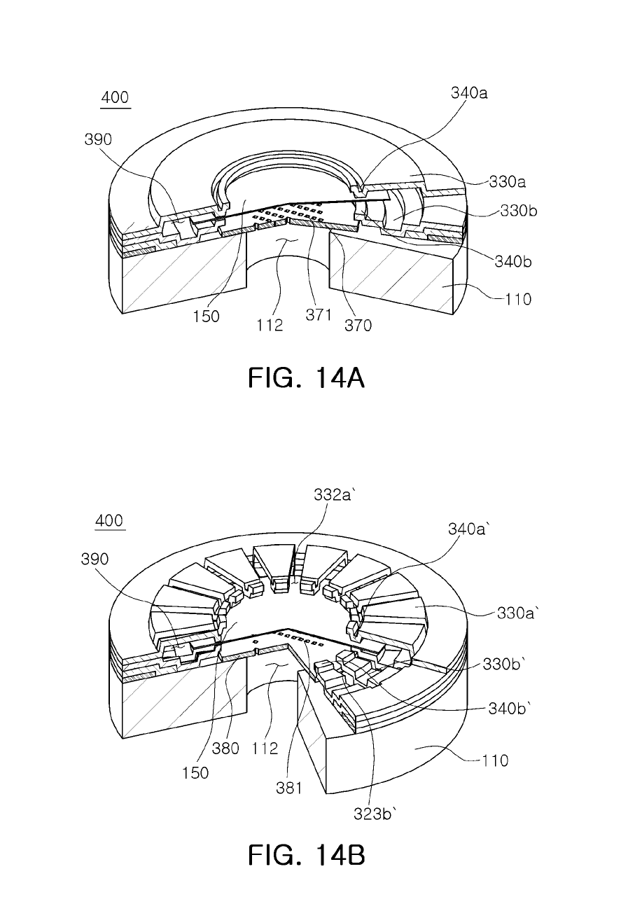

Hereinafter, an acoustic transducer 400 according to the fourth embodiment of the present invention will be described with reference to the FIGS. 14A through 16B. However, the same components as the above-mentioned components will be denoted by the same reference numerals and a detailed description thereof will be omitted.

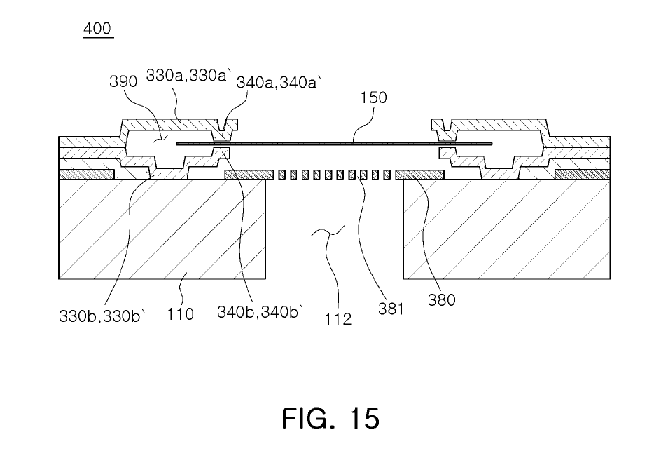

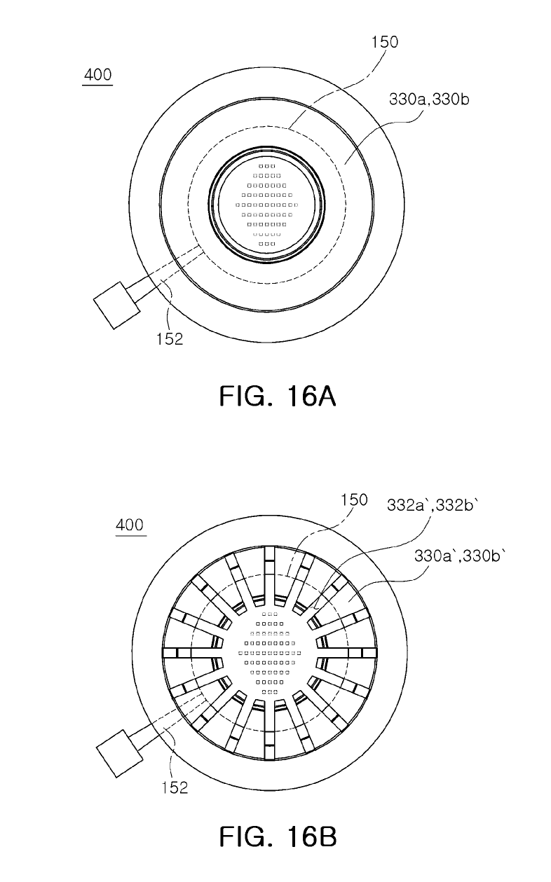

FIGS. 14A and 14B are partially cut-away perspective views of the acoustic transducers 400 according to the fourth embodiment of the present invention, FIG. 15 is a cross-sectional view of the acoustic transducers 400 shown in FIGS. 14A and 14B, and FIGS. 16A and 16B are plan views of the acoustic transducers 400 shown in FIGS. 14A and 14B, respectively.

Referring to FIGS. 14A to 16B, the acoustic transducer 400 according to the fourth embodiment of the present invention may include a substrate 110 including a hollow part 112, a second support structure 330b or 330b′ attached onto an upper surface of the substrate, a first support structure 330a or 330a′, a thin film type diaphragm 150 positioned between the first and second support structures 330a or 330a′ and 330b or 330b′, and a lower fixed electrode 380 positioned below the diaphragm 150 to cover the hollow part.

In other words, the acoustic transducer 400 according to the fourth embodiment of the present invention may be have a form in which the back plate 120 and the fixed upper electrode 160 are excluded from the above-mentioned acoustic transducer 300 according to the third embodiment of the present invention.

The acoustic transducer 400 according to the fourth embodiment of the present invention may signal the sound in a manner of measuring a change in capacitance of a capacitor formed by interaction between the diaphragm 150 and the lower fixed electrode 380 due to vibration of the diaphragm 150 caused by acoustic pressure.

As set forth above, according to the present invention, the degree of freedom in vertical vibration of the diaphragm may be improved, such that the sensitivity of sensing the acoustic waves may be improved.

While the present invention has been shown and described in connection with the embodiments, it will be apparent to those skilled in the art that modifications and variations can be made without departing from the spirit and scope of the invention as defined by the appended claims.

What is claimed is:

1. An acoustic transducer comprising:
a substrate formed to have a hollow part through which acoustic waves are input;
a diaphragm formed on the substrate and covering the hollow part; and
a back plate disposed so as to cover at least a portion of the diaphragm,
wherein a ring-shaped groove extended along an edge of the diaphragm is formed in the substrate.

2. The acoustic transducer of claim 1, wherein the back plate includes a support part extended toward the edge of the diaphragm.

3. The acoustic transducer of claim 2, wherein a longitudinal cross section of the support part has a trapezoidal, triangular, or semi-circular shape.

4. The acoustic transducer of claim 1, wherein the diaphragm is formed of a conductive material and the back plate includes a fixed upper electrode formed thereon, such that an electric field is formed between the diaphragm and the back plate.

5. The acoustic transducer of claim 1, wherein a support structure is formed between the diaphragm and the back plate.

6. The acoustic transducer of claim 1, wherein the support part is disposed to have a circular shape at a predetermined interval based on the diaphragm.

7. The acoustic transducer of claim 1, wherein the support part is ring-shaped, having a predetermined diameter based on the diaphragm.

8. The acoustic transducer of claim 1, wherein the groove has a cross-sectional shape in which a depth of the groove increases as a distance from the diaphragm increases.

9. An acoustic transducer comprising:
a substrate formed to have a hollow part through which acoustic waves are input;
a diaphragm formed on the substrate, covering the hollow part, and formed of a conductive material;
a back plate including a fixed upper electrode formed thereon; and
a support structure formed between the diaphragm and the back plate and including a support part extended toward an edge of the diaphragm,
wherein a ring-shaped groove extended along the edge of the diaphragm is formed in the substrate.

10. The acoustic transducer of claim 9, wherein the support part is disposed to have a circular shape at a predetermined interval based on the diaphragm.

11. The acoustic transducer of claim 9, wherein the support part is ring-shaped, having a predetermined diameter based on the diaphragm.

12. The acoustic transducer of claim 9, wherein the groove has a cross-sectional shape in which a depth of the groove increases as a distance from the diaphragm increases.

13. The acoustic transducer of claim 9, wherein a longitudinal cross section of the support part has a trapezoidal, triangular, or semi-circular shape.

14. An acoustic transducer comprising:
a substrate including a hollow part;
a second support structure including a second support part protruding upwardly along an outer side of the hollow part and attached onto an upper surface of the substrate;
a first support structure including a first support part protruding downwardly at a position corresponding to the second support part;
a thin film type diaphragm positioned between the first and second support parts and having an outer line formed at the outside of an inner surface of an upper end of the hollow part in a radial direction so as to completely cover the hollow part; and
a fixed upper electrode provided over the diaphragm to form a capacitor through interaction with the diaphragm in a position facing the diaphragm.

15. The acoustic transducer of claim 14, wherein the diaphragm is positioned to be spaced apart from the first and second support parts.

16. The acoustic transducer of claim 14 further comprising:
a back plate including a plurality of sound holes and fixed to the first support structure,
wherein the fixed upper electrode is attached to a lower surface of the back plate.

17. The acoustic transducer of claim 14, wherein the second support structure is spaced apart from the upper surface of the substrate at a predetermined section in the radial direction to thereby have elasticity in a vertical direction, and the first support structure is spaced apart from a lower surface of the fixed upper electrode at a predetermined section in the radial direction to thereby have elasticity in the vertical direction.

18. The acoustic transducer of claim 14, further comprising an auxiliary plate attached to the upper surface of the substrate, positioned below the diaphragm, covering the hollow part, and including a plurality of holes.

19. The acoustic transducer of claim 18, wherein the auxiliary plate is a lower fixed electrode formed of a conductive material so as to form a capacitor through interaction with the diaphragm.

20. The acoustic transducer of claim 14, wherein the first and second support parts have a continuous closed curve shape.

21. The acoustic transducer of claim 14, wherein the first and second support parts are a plurality of bumps, and the first and second support structures have a saw-tooth shape having groove parts between the first and second supports parts, respectively.

22. The acoustic transducer of claim 14, wherein the diaphragm has a disk shape.

23. An acoustic transducer comprising:
a substrate including a hollow part;
a second support structure including a second support part protruding upwardly along an outer side of the hollow part and attached onto an upper surface of the substrate;
a first support structure including a first support part protruding downwardly at a position corresponding to the second support part;
a thin film type diaphragm positioned between the first and second support parts and having an outer line formed at the outside of an inner surface of an upper end of the hollow in a radial direction so as to completely cover the hollow part; and
a lower fixed electrode attached onto the upper surface of the substrate, positioned below the diaphragm, including a plurality of holes, and formed of a conductive material so as to form a capacitor through interaction with the diaphragm.

24. The acoustic transducer of claim 23, wherein the diaphragm is positioned to be spaced apart from the first and second support parts.

25. The acoustic transducer of claim 23, wherein the first support structure is spaced apart from the upper surface of the substrate at a predetermined section in the radial direction to thereby have elasticity in a vertical direction.

26. The acoustic transducer of claim 23, wherein the first and second support parts have a continuous closed curve shape.

27. The acoustic transducer of claim 23, wherein the first and second support parts are a plurality of bumps, and the first and second support structures have a saw-tooth shape having groove parts between the first and second supports parts, respectively.

28. The acoustic transducer of claim 23, wherein the diaphragm has a disk shape.
